(19) United States
(12) Patent Application Publication
(10) Pub. No.: US 2025/0387872 A1
(43) Pub. Date: Dec. 25, 2025

(54) POLISHING PAD WITH THERMAL MANAGEMENT FEATURES

(71) Applicants: DuPont Electronic Materials Holding, Inc., Newark, DE (US); DuPont Specialty Products USA, LLC, Wilmington, DE (US)

(72) Inventors: Matthew R. Gadinski, Oxford, PA (US); Dave Hui, Glen Mills, PA (US); Matthew Richard Van Hanehem, Middletown, DE (US); Cameron Shelton, Middletown, DE (US); Jeffrey Scott Meth, Landenberg, PA (US); Jason Strader, Pepper Pike, OH (US)

(21) Appl. No.: 18/750,740

(22) Filed: Jun. 21, 2024

(51) Int. Cl. B24B 37/22

(52) U.S. Cl. CPC B24B 37/22

(57) ABSTRACT

A polishing pad for chemical mechanical polishing comprises a polishing layer and an adjacent subpad layer. The polishing layer includes a polishing surface, a polishing layer interface surface opposite the polishing surface, a polishing layer thickness extending from the polishing surface to the polishing layer interface surface, and recesses extending from the polishing layer surface toward the polishing layer interface surface. A depth of the recesses is at least 80% the polishing layer thickness. The subpad layer has a subpad interface surface adjacent to the polishing layer interface surface and a bottom surface opposite the subpad interface surface. The subpad layer has a thermal conductivity of 1 to 35 Watts/m-K. The combination of the deep grooves in the top layer and the thermal conductivity of the subpad layer can facilitate thermal management at the polishing interface during polishing of a substrate.

### FIELD OF THE INVENTION

The field of the invention is polishing pads used in chemical mechanical polishing.

### BACKGROUND OF THE INVENTION

Chemical Mechanical Planarization (CMP) is a variation of a polishing process that is widely used to flatten, or planarize, the layers of construction of an integrated circuit or similar structure. Particularly, CMP is frequently used to produce planar-uniform layers of a defined thickness in the manufacture of three-dimensional circuit structures through additive stacking and planarizing. CMP can remove excess deposited material on the substrate (e.g., wafer) surface to produce an extremely flat layer of a uniform thickness, with uniformity extending across the entire substrate (e.g., wafer) area. When the uniform thickness is across the entire wafer, it is known as global uniformity.

CMP utilizes a liquid, often called slurry, which can contain nano-sized particles. The slurry is fed onto the surface of a rotating multilayer polymer pad (sometimes referred to as polishing sheet), the pad being mounted on a rotating platen. The polishing pad includes a polishing layer and can include a subpad. Substrates (e.g., wafers) are mounted into a separate fixture, or carrier, which has a separate means of rotation, and pressed against the surface of the pad under a controlled load. This can lead to a high rate of relative motion between the substrate (e.g., wafer) and the polishing pad and a resulting high rate of shear or abrasion at both the substrate and the pad surface. The shear and the slurry particles trapped at the pad/substrate junction abrade the substrate (e.g., wafer) surface, leading to removal of material from the substrate surface. Control of removal rate and the uniformity of removal are important. The temperature at which polishing occurs and heat generated during polishing can impact the efficiency of the polishing process. As far as known, there are no CMP polishing pads commercially available that facilitate heat transfer through the pad when using a temperature controlled devices such as a temperature controlled platen.

The polishing pads comprise polymeric materials that generally may be porous. Accordingly, the polishing pads are generally thermally insulating. This can make control of the polish temperature challenging.

### SUMMARY OF THE INVENTION

Disclosed herein is a polishing pad for chemical mechanical polishing comprising a polishing layer and a subpad layer. The polishing layer has a polishing surface, a polishing layer interface surface opposite the polishing surface, a polishing layer thickness, t, extending from the polishing surface to the polishing layer interface surface, and recesses extending from the polishing layer surface toward the polishing layer interface surface, wherein a depth, d, of the recesses is at least 80% or the polishing layer thickness. The subpad layer has a subpad interface surface adjacent to the polishing layer interface surface and a bottom surface opposite the subpad interface surface. The subpad layer has a thermal conductivity of 1 to 35 Watts/m-K.

Also disclosed herein is a method polishing comprising providing a substrate to be polished; providing the polishing pad as described herein on a platen; providing a slurry on the polishing pad, and polishing by moving the substrate relative to the polishing pad, wherein the platen includes thermal control features.

### BRIEF DESCRIPTION OF THE DRAWINGS

Referring now to the figures, which are exemplary embodiments, and wherein the like elements are numbered alike.

FIG. 1 is a top view of an example of a polishing pad as disclosed herein.

FIG. 2 is a cross section view at through the thickness of a polishing pad as in FIG. 1 at a-a′, showing one embodiment of a polishing pad as disclosed herein.

FIG. 3 is a cross section view at through the thickness of a polishing pad as in FIG. 1 at a-a′, showing a second embodiment of a polishing pad as disclosed herein.

FIG. 4 is a graph of true stress vs. true strain for sample pads as shown in Example 4.

### DETAILED DESCRIPTION OF THE INVENTION

Disclosed herein is a polishing pad useful in chemical mechanical polishing. This polishing pad can provide advantageous thermal properties to facilitate management of the polishing temperature.

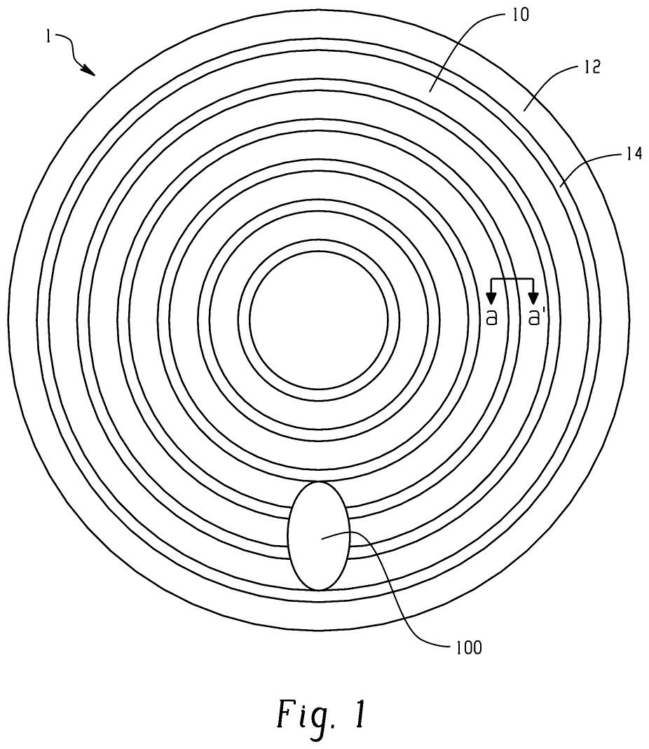

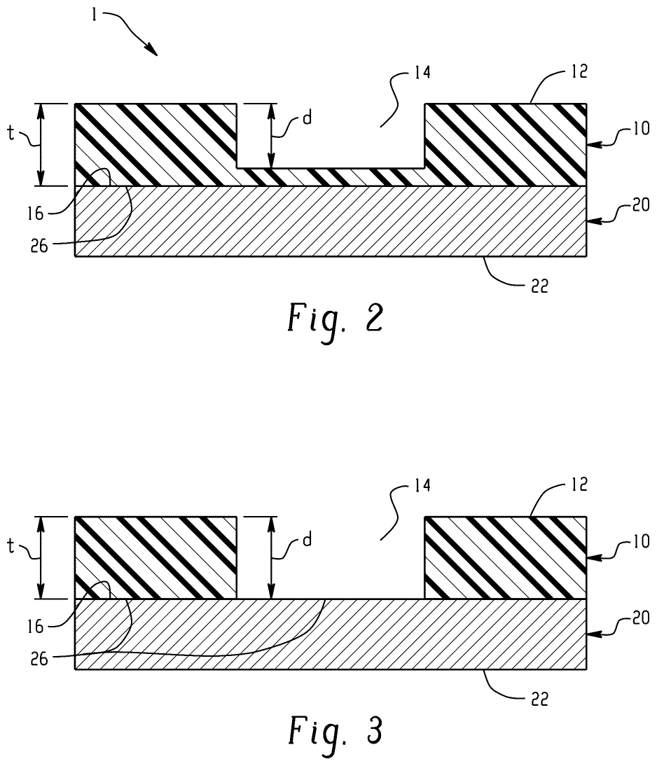

As shown in FIGS. 1-3, the pad 1 has a polishing layer 10 and a subpad 20. The polishing layer has a top polishing surface 12, a polishing layer interface surface 16, and a thickness, t. Optional recesses 14, which are shown in FIG. 1 as concentric grooves, can be found in the polishing layer 10. The recesses 14 are shown as concentric grooves, but other recess shapes such as radial grooves extending from the center of the pad, crosshatch grooves, or a combination thereof could be used. Presence of the recesses is preferred. The recesses 14 have a depth, d. For new pads, the depth, d, can be at least 80, at least 90, at least 95, at least 98% of the thickness t as shown in FIG. 2. As the polishing layer 10 of FIG. 2 wears from top to bottom during polishing and diamond conditioning, then this percentage decreases. Optionally, for higher heat flow, the thickness, t, can be 100% of the thickness, t, as shown in FIG. 3. As the polishing layer 10 of FIG. 3 wears from top to bottom, then this percentage remains constant at 100% of the thickness.

The subpad 20 has a subpad interface surface 26 and a subpad bottom surface 22. Pressure sensitive or hot melt adhesives, not shown, can combine the subpad to the polishing layer. The polishing pad 1 can include an optional end point detection window 100.

The polishing layer thickness, t, can be, for example, from 0.5 or from 1 mm up to 4, up to 3, or up to 2 mm. The subpad layer thickness can be, for example, 0.5 or from 1 mm up to 4, up to 3, up to 2, or up to 1.5 mm.

The amount of top pad material at the bottom of the recess can be less than 0.5, less than 0.4, less than 0.3, less than 0.2 or less than 0.1 mm or all top pad material can be removed in the recess exposing the underlying layer, e.g. subpad.

The polishing layer 10 can comprise a polymer. The polishing layer 10 can be porous. Pores can be provided, for example, by addition of hollow flexible polymer elements (e.g., hollow microspheres), blowing agents, frothing or supercritical carbon dioxide. Examples of polymeric materials for the polishing layer include polyurethanes, polycarbonates, polysulfones, nylons, polyethers, polyesters, polystyrenes, acrylic polymers, polymethyl methacrylates, polyvinylchlorides, polyvinyl fluorides, polyethylenes, polypropylenes, polybutadienes, polyethylene imines, polyether sulfones, polyamides, polyether imides, polyketones, epoxy resins, silicones, copolymers thereof (such as, polyether-polyester copolymers), and combinations or blends thereof. The polishing layer can comprise a polymer that is a polyurethane formed by reaction of one or more polyfunctional isocyanates and one or more polyols. For example, a polyisocyanate terminated urethane prepolymer can be used. The polyfunctional isocyanate used in the formation of the polishing layer of the chemical mechanical polishing pad of the present invention can be selected from the group consisting of an aliphatic polyfunctional isocyanate, an aromatic polyfunctional isocyanate and a mixture thereof. For example, the polyfunctional isocyanate used in the formation of the polishing layer of the chemical mechanical polishing pad of the present invention can be a diisocyanate selected from the group consisting of 2,4-toluene diisocyanate; 2,6-toluene diisocyanate; 4,4′-diphenylmethane diisocyanate; naphthalene-1,5-diisocyanate; tolidine diisocyanate; para-phenylene diisocyanate; xylylene diisocyanate; isophorone diisocyanate; hexamethylene diisocyanate; 4,4′-dicyclohexylmethane diisocyanate; cyclohexanediisocyanate; and, mixtures thereof. The polyfunctional isocyanate can be an isocyanate terminated urethane prepolymer formed by the reaction of a diisocyanate with a prepolymer polyol. The isocyanate-terminated urethane prepolymer can have 2 to 12 wt. %, 2 to 10 wt. %, 4 to 8 wt. % or 5 to 7 wt. % unreacted isocyanate (NCO) groups. The prepolymer polyol used to form the polyfunctional isocyanate terminated urethane prepolymer can be selected from the group consisting of diols, polyols, polyol diols, copolymers thereof and mixtures thereof. For example, the prepolymer polyol can be selected from the group consisting of polyether polyols (e.g., poly(oxytetramethylene)glycol, poly(oxypropylene)glycol and mixtures thereof); polycarbonate polyols; polyester polyols; polycaprolactone polyols; mixtures thereof; and, mixtures thereof with one or more low molecular weight polyols selected from the group consisting of ethylene glycol; 1,2-propylene glycol; 1,3-propylene glycol; 1,2-butanediol; 1,3-butanediol; 2-methyl-1,3-propanediol; 1,4-butanediol; neopentyl glycol; 1,5-pentanediol; 3-methyl-1,5-pentanediol; 1,6-hexanediol; diethylene glycol; dipropylene glycol; and, tripropylene glycol. For example, the prepolymer polyol can be selected from the group consisting of polytetramethylene ether glycol (PTMEG); ester based polyols (such as ethylene adipates, butylene adipates); polypropylene ether glycols (PPG); polycaprolactone polyols; copolymers thereof; and mixtures thereof. For example, the prepolymer polyol can be selected from the group consisting of PTMEG and PPG. When the prepolymer polyol is PTMEG, the isocyanate terminated urethane prepolymer can have an unreacted isocyanate (NCO) concentration of 2 to 10 wt. % (more preferably of 4 to 8 wt. %; most preferably 6 to 7 wt. %). Examples of commercially available PTMEG based isocyanate terminated urethane prepolymers include Imuthane® prepolymers (available from COIM USA, Inc., such as, PET-80A, PET-85A, PET-90A, PET-93A, PET-95A, PET-60D, PET-70D, PET-75D); Adiprene® prepolymers (available from Chemtura, such as, LF 800A, LF 900A, LF 910A, LF 930A, LF 931A, LF 939A, LF 950A, LF 952A, LF 600D, LF 601D, LF 650D, LF 667, LF 700D, LF750D, LF751D, LF752D, LF753D and L325); Andur® prepolymers (available from Anderson Development Company, such as, 70APLF, 80APLF, 85APLF, 90APLF, 95APLF, 60DPLF, 70APLF, 75APLF). When the prepolymer polyol is PPG, the isocyanate terminated urethane prepolymer can have an unreacted isocyanate (NCO) concentration of 3 to 9 wt. % (more preferably 4 to 8 wt. %, most preferably 5 to 6 wt. %). Examples of commercially available PPG based isocyanate terminated urethane prepolymers include Imuthane® prepolymers (available from COIM USA, Inc., such as, PPT-80A, PPT-90A, PPT-95A, PPT-65D, PPT-75D); Adiprene® prepolymers (available from Chemtura, such as, LFG 963A, LFG 964A, LFG 740D); and Andur® prepolymers (available from Anderson Development Company, such as, 8000APLF, 9500APLF, 6500DPLF, 7501DPLF). The isocyanate terminated urethane prepolymer can be a low free isocyanate terminated urethane prepolymer having less than 0.1 wt. % free toluene diisocyanate (TDI) monomer content. Non-TDI based isocyanate terminated urethane prepolymers can also be used. For example, isocyanate terminated urethane prepolymers include those formed by the reaction of 4,4′-diphenylmethane diisocyanate (MDI) and polyols such as polytetramethylene glycol (PTMEG) with optional diols such as 1,4-butanediol (BDO) are acceptable. When such isocyanate terminated urethane prepolymers are used, the unreacted isocyanate (NCO) concentration is preferably 4 to 10 wt. % (more preferably 4 to 10 wt. %, most preferably 5 to 10 wt. %). Examples of commercially available isocyanate terminated urethane prepolymers in this category include Imuthane® prepolymers (available from COIM USA, Inc. such as 27-85A, 27-90A, 27-95A); Andur® prepolymers (available from Anderson Development Company, such as, IE75AP, IE80AP, IE 85AP, IE90AP, IE95AP, IE98AP); and Vibrathane® prepolymers (available from Chemtura, such as, B625, B635, B821).

The subpad comprises a particulate filler in a polymeric matrix material. The particulate filler can be thermally conductive such the subpad can have a thermal conductivity of the subpad of greater than 1, at least 2, or at least 3 Watts per meter per degree Kelvin (W/m-K) and can be up to 20 or up to 10 W/m-K. Advantageously, the thermal conductivity is 1 to 35 W/m-K. More advantageously, the thermal conductivity is 2 to 20 W/m-K. Most advantageously, the thermal conductivity is 2 to 10 W/m-K.

The thermal conductivity was measured using a device such as a Thermal Interface Material Tester or by following the ASTMD5470 for measurement of thermal resistance and conductivity on thin materials. For example, a Thermal Interface Material Tester from Analysis Tech can be used. For example, five samples of 1 inch (2.54 cm) diameter subpad material were sequentially stacked and placed between a hot and cold surface with applied load starting at room temperature and allowed to equilibrate to determine heat flux. The samples are loaded sequentially on top of one another applying silicone oil in between to limit interfacial effects. A plot of heat flux versus thickness that can then be used to determine thermal conductivity from the slope of the plot.

The thermal conductivity of the sub-pad can be consistent from edge to edge of the pad. The thermal conductive of the sub-pad can be consistent through the thickness of the pad or there may be a variation in thermal conductivity through the thickness of the pad. The subpad layer can be non-porous.

The subpad layer 20 can have a modulus at compression pressures of up to 48 kilopascals (kPa) (e.g., pressures of 24 to 48 kPA) of from 1 to less than 5 megaPascals (MPa) and a modulus at compression pressures of 48 to 76 kilopascals (Pa) under compress of 5 to 20 MPa. The subpad can have a true strain of less than or equal to 10% over compression pressures of up to 1.2 MPa. These modulus and strain values can be measured using the following procedure: An indentation test can be carried out on MTS-Electromechanical Test Systems-Criterion 43 equipped with 1 kilonewton (kN) Load Cell and compression platens. The top platen can be modified to include ˜10 mm radius stainless steel indenter at the center and capacitance sensors around the indenter for displacement measurements between platens. The sample size can be die cut 2-inch radius circle with sample thickness. The indenter is moved downward at fixed crosshead velocity until the load reaches specified force value and moves to the original position with the same velocity. The resultant force vs displacement curve was converted to true stress vs true strain curve and used to calculate secant modulus of elasticity values using the loading curve.

The particles preferably are not electrically conductive. The particles can be inorganic. The particles can be lamellar (i.e., have a platelike shape, have multiple layers of the inorganic material or both. Examples of lamellar particles include boron nitride particles and graphite. Examples particularly of thermally conductive particles can be, for example, aluminum oxide, boron nitride, aluminum nitride, magnesium oxide and zinc oxide. Boron nitride particles are preferred. The particles (e.g., boron nitride particles) can have, for examples, a particles size up to 30 microns, such as 1 to 20 microns or 1 to 15 microns as observed by scanning electron microscopy. The amount of the particles, such as boron nitride, can be from 40, from 50, or from 60 up to 90, up to 85, up to 80, or up to 75 weight percent based on total weight of the conductive polymers and the polymeric matrix material.

The polymeric matrix material can comprise a first material selected from one of more of vinyl silicon resin, polyisobutylene polymer, organic silicon rubber, polyurethane, methyl methacrylate, organopolysiloxane, acrylate and polyamide resin, preferably organic silicon rubber, and a second material selected from petroleum-based resin, silicone resins, such as MQ silicone resin, polyol, ethyl acrylate, rosin and ethylene phenyl acetate resin, preferably silicone resin, Where the polymeric matrix comprises for example organic silicon rubber and silicone resin, the polymeric matrix can include, for example 2 to 80, preferably 15 to 35 weight percent of a silicon resin and 20 to 98, preferably 65 to 85 weight percent of a silicone rubber based on total weight of the polymeric matrix.

Optionally, a supporting structure non-woven cloth can be used where the combination of conductive particles and polymeric matrix can be applied to or impregnated in the supporting structure. Where a support is used, it can have thickness of, for example, from 5 or from 10 up to 40 or up to 30 microns. Where a support is used, the thermal conductivity may vary through the thickness of the subpad.

The polishing pads as disclosed herein having a thermally conductive subpad with grooves in the top pad can provide pads with relatively low thermal resistance and good thermal conductivity. These pads can facilitate thermal management at the polishing surface. For example, with the polishing pads as disclosed herein the polishing surface may heat and cool more slowly during conventional polishing, which can provide a more stable temperature profile at the polishing surface during polishing. When using a heated or cooled platen, such as a water-heated or water-cooled platen, then the polishing surface may be heated or cooled more quickly. In summary, the pads of the invention facilitate heat transfer through the pad when using a temperature controlled devices such as temperature controlled platens. This may lead to more consistent removal rates. In addition, the thermal conductivity of the subpad may enhance the effect of a heat control system built into the platen of a polishing device by facilitating heat transfer through the pad.

The polishing pad as disclosed herein may provide desirable polishing properties (e.g., one or more of desired removal rate, consistency of polishing across the diameter of the pad, low defects, consistency of polishing when used in polishing a series of substrates).

The polishing pads as disclosed herein can be made for example by first forming the polishing layer. Then the subpad layer is applied to the polishing layer. For example, the subpad layer can be adhered to the polishing layer interface surface using an adhesive. Alternatively, a subpad precursor composition comprising the thermally conductive polymers in a precursor to the matrix material can be applied to the polishing layer interface surface and then cured. The grooving of the polishing layer will typically occur after forming of the polishing layer/subpad stack and when the grooves extend 100% of the thickness of the polishing layer should occur after formation of the polishing layer/subpad layer stack.

### EXAMPLES

### Example 1

Various subpad compositions combined with various toppad (polishing layer) thicknesses were evaluated to identify thermal resistance through the pad. In each instance shown in Table 1, the sub-pad thickness was 50 mil (1.27 mm) composed of a 20 and 30 mil (0.51 and 0.76 mm) layers adhered together with an adhesive, the top pad is a porous polyurethane based material. The composition (and as a result subpad conductivity) of the subpad and thickness of the toppad (polishing layer) were varied. Samples 1A-1D and 2A-2D with low thermal conductivity subpad materials have high thermal resistance regardless of the thickness of the top pad. When the thermal conductivity of the subpad material is higher as in Samples 3A-D, 4A-D, and 4A-D, the thickness of the toppad impacts the thermal resistance of the pad construction. This indicates that to obtain desired heat transfer properties in the pad, a combination of relatively high thermal conductivity subpad material with recesses that extend to or close to the subpad material can provide good thermal management capability in the pad. Notably, at top pad thickness of about 1 mm or more there is little difference in thermal resistance of pads with subpad conductivities in the range of 5-34 W/m-K. Similar trends were also seen to sub-pad thickness of 20 mil (0.508 mm).

TABLE 1

| | | Thermal | | |
|---|---|---|---|---|
| | | Conductivity | | Thermal |
| | Sub-pad | of Subpad | top pad | Resistance |
| Sample ID | description | (W/m-K) | thickness (mm) | (W/m²K) |
| 1A(Comparative) | Commercial | 0.02 | 2.032 | 7.07E−02 |
| 1BA2 | sub-pad. | | 1.016 | 6.78E−02 |
| (Comparative) | Porous | | | |
| 1C | polyurethane | | 0.254 | 6.46E−02 |
| (Comparative) | with non- | | | |
| 1D | woven | | 0 | 6.35E−02 |
| (Comparative) | support | | | |
| 2A Comparative) | Polyurethane. | 0.283 | 2.032 | 1.30E−02 |
| 2B(Comparative) | Non-porous. | 0.283 | 1.016 | 8.76E−03 |
| 2C(Comparative) | | 0.283 | 0.254 | 5.55E−03 |
| 2D(Comparative) | | 0.283 | 0 | 4.49E−03 |
| 3A | Boron nitride | 5 | 2.032 | 8.79E−03 |
| 3B | in silicone | 5 | 1.016 | 4.52E−03 |
| 3C | matrix on | 5 | 0.254 | 1.32E−03 |
| 3D | non-woven | 5 | 0 | 2.54E−04 |
| | support | | | |
| 4A | Boron nitride | 7.8 | 2.032 | 8.70E−03 |
| 4B | in silicone | 7.8 | 1.016 | 4.43E−03 |
| 4C | matrix on | 7.8 | 0.254 | 1.23E−03 |
| 4D | non-woven | 7.8 | 0 | 1.63E−04 |
| | support | | | |
| 5A | Boron nitride | 34 | 2.032 | 8.58E−03 |
| 5B | in silicone | 34 | 1.016 | 4.31E−03 |
| 5C | matrix on | 34 | 0.254 | 1.10E−03 |
| 5D | non-woven | 34 | 0 | 3.74E−05 |
| | support | | | |

### Example 2

Polishing pads were prepared using two-sided pressure sensitive adhesive to fix the subpad to the polishing layer. The control pad was a commercially available pad having a porous polyurethane subpad on a non-woven support. Thermal conductivity of this sub-pad is approximately 0.02 W/m-K. Inventive pads, F and G used a boron nitride containing, non-porous subpad on a non-woven support that has a thermal conductivity of about 5 W/m-K. The grooving pattern was consistent across the samples, however, the groove on Inventive Pad F did not expose the underlying subpad while the grooves on Inventive Pad G did expose the underlying subpad.

The pads were placed on a platen, brought into contact with a wafer, and rotated. Hot water (approximately 50° C.) was applied to the surface of the pad for 3 minutes followed by application or room temperature water for 3 minutes. The temperature at the surface was monitored with an IR gun. The data showed that the temperature of the polishing layer surface of the control pad increased more quickly and reached a higher value while the hot water was applied compared to the inventive pads F and G. However, when the room temperature water was applied the control pad cooled more quickly and to a lower level than the inventive pads F and G. This shows that the inventive pads can be effective at moderating temperature fluctuations during polishing. Similarly, for the pad F with grooving that did not expose the subpad the temperature of the polishing layer surface increased more quickly and reached a higher value while the hot water was applied compared to the inventive pad G where grooving reached the subpad layer, and when the room temperature water was applied the inventive pad F cooled more quickly and to a lower level than the inventive pad G.

### Example 3

Control pads with a porous subpad of polyurethane impregnated on a non-woven (having a thermal conductivity of 0.02 W/m-K) and inventive pads having a subpad of boron nitride in a silicone matrix composition (having a thermal conductivity of 5 W/m-K) were tested each polishing a series of wafers. Pressure sensitive adhesive combined the subpads to the polishing layer. The inventive pads showed a significant increase in removal rate with wafer count while than the control pads show less variation. This is consistent with the temperature data as the controls equilibrated quickly and were primarily stable whereas the inventive pads took several wafers to plateau in temperature. This demonstrates that polishing performance can be influenced by altering the temperature with pads as disclosed herein.

### Example 4

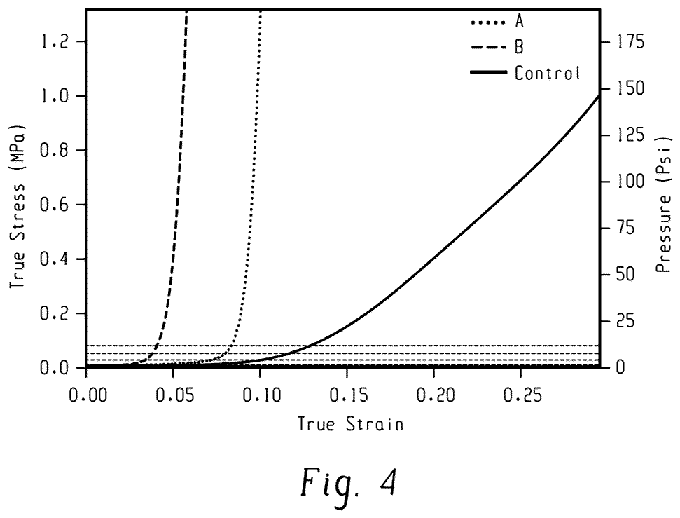

Various subpad materials were evaluated for modulus and strain under compression using the procedure described herein. The control subpad material is a porous polyurethane on a non-woven support used in certain commercial polishing pads. The other subpad materials as are useful in the pads disclosed herein were various thicknesses of a material comprising boron nitride in a silicone matrix on a non-woven substrate. The subpad materials used in the inventive pads show significantly different strain behavior as shown in FIG. 4. The modulus for the samples are as in Table 2.

TABLE 2

| | Average Elastic Modulus | Average Elastic Modulus |
|---|---|---|
| | (MPa) at compression | (MPa) at compression |
| | pressures of 24 to 48 | pressures of 48 to 76 |
| Sample ID | kiloPascals | kiloPascals |
| Control | 1.3 | 2.3 |
| A | 4.1 | 8.8 |
| B | 7.2 | 13.5 |

### Example 5

Pads having both radial and concentric grooving pattern were tested for polishing performance. The results are shown in Table 3.

TABLE 3

| | | Subpad | Removal | Removal |
|---|---|---|---|---|
| Sample | Subpad type | thickness (mm) | performance | consistency |
| Control | Porous | 1.27 | Acceptable | Faster removal |
| | polyurethane | | | rate at center of |
| | impregnated | | | polishing pad, |
| | non-woven | | | removal rate |
| | substrate | | | decreases with |
| | | | | increasing |
| | | | | distance from |
| | | | | center, removal |
| | | | | rate shows |
| | | | | decrease near |
| | | | | edge of the pad. |
| C | Boron nitride in | 0.508 | Acceptable | Faster removal |
| | silicone matrix | | | rate at center of |
| | on non-woven | | | polishing pad, |
| | substrate, non- | | | removal rate |
| | porous | | | decreases with |
| | | | | increasing |
| | | | | distance from |
| | | | | center, removal |
| | | | | rate shows |
| | | | | decrease near |
| | | | | edge of the pad |
| D | Boron nitride in | 0.762 | Acceptable | Faster removal |
| | silicone matrix | | | rate at center of |
| | on non-woven | | | polishing pad, |
| | substrate, non- | | | removal rate |
| | porous | | | decreases with |
| | | | | increasing |
| | | | | distance from |
| | | | | center, removal |
| | | | | rate shows |
| | | | | decrease near |
| | | | | edge of the pad |
| E | Boron nitride in | 1.27 | Acceptable | Faster removal |
| | silicone matrix | | | rate at center of |
| | on non-woven | | | polishing pad, |
| | substrate, non- | | | removal rate is |
| | porous | | | relatively |
| | | | | constant as |
| | | | | distance from |
| | | | | center but |
| | | | | decreases |
| | | | | significantly |
| | | | | near edge of pad. |

This disclosure further encompasses the following aspects.

Aspect 1: A polishing pad for chemical mechanical polishing comprising: a polishing layer having a polishing surface, a polishing layer interface surface opposite the polishing surface, a polishing layer thickness extending from the polishing surface to the polishing layer interface surface, and recesses extending from the polishing layer surface toward the polishing layer interface surface, wherein a depth of the recesses is at least 80% the polishing layer thickness; a subpad layer having a subpad interface surface adjacent to the polishing layer interface surface and a bottom surface opposite the subpad interface surface, the subpad layer comprising a subpad material; wherein the subpad layer has a thermal conductivity of greater than 1, preferably 1 to 40, more preferably 2 to 35, yet more preferably 3 to 25 Watts/m-K.

Aspect 2: The polishing pad of Aspect 1 wherein the recesses extend to the polishing layer interface surface.

Aspect 3: The polishing pad of Aspect 1 wherein the recesses expose the subpad interface surface.

Aspect 4: The polishing pad of any one of the previous Aspects wherein the subpad layer has a consistent thermal conductivity throughout the subpad material.

Aspect 5: The polishing pad of any one of the previous Aspects wherein the subpad material comprises boron nitride particles in a polymeric matrix material.

Aspect 6: The polishing pad of Aspect 5 wherein the boron nitride particles are present in an amount of 40 to 90, preferably 45 to 85, more preferably 50 to 80 weight percent based on total weight of the boron nitride and the polymeric matrix material.

Aspect 7: The polishing pad of Aspect 5 or 6 wherein the polymeric matrix material comprises a silicone composition.

Aspect 8: The polishing pad of Aspect 7 wherein the silicone composition comprises 2 to 80 weight percent silicone adhesive and 20 to 98 weight percent silicone rubber based on total weight of the silicone composition.

Aspect 9: The polishing pad of any one of the previous Aspects wherein the subpad material is provided on a woven or non-woven material scaffold.

Aspect 10: The polishing pad of any one of the previous Aspects wherein the subpad layer has an elastic modulus under compression at pressures of from 24 to less than 48 kPa of 1 to 5 MPa and an elastic modulus under compression at pressures of 38 to 76 kilopascals of 5 to 20 MPa and a true strain of less than or equal to 10% over compression pressures of up to 1.2 MPa.

Aspect 11: A method of polishing comprising providing a substrate to be polished, providing the polishing pad as in any one of the previous Aspects on a platen, providing a slurry on the polishing pad, polishing by moving the substrate relative to the polishing pad, wherein the platen includes thermal control features.

All ranges disclosed herein are inclusive of the endpoints, and the endpoints are independently combinable with each other (e.g., ranges of “up to 25 wt. %, or, more specifically, 5 wt. % to 20 wt. %”, is inclusive of the endpoints and all intermediate values of the ranges of “5 wt. % to 25 wt. %,” etc.). Moreover, stated upper and lower limits can be combined to form ranges (e.g., “at least 1 or at least 2 weight percent” and “up to 10 or 5 weight percent” can be combined as the ranges “1 to 10 weight percent”, or “1 to 5 weight percent” or “2 to 10 weight percent” or “2 to 5 weight percent”).

The disclosure may alternately comprise, consist of, or consist essentially of, any appropriate components herein disclosed. The disclosure may additionally, or alternatively, be formulated so as to be devoid, or substantially free, of any components, materials, ingredients, adjuvants or species used in the prior art compositions or that are otherwise not necessary to the achievement of the function or objectives of the present disclosure.

All cited patents, patent applications, and other references are incorporated herein by reference in their entirety. However, if a term in the present application contradicts or conflicts with a term in the incorporated reference, the term from the present application takes precedence over the conflicting term from the incorporated reference.

Unless specified to the contrary herein, all test standards are the most recent standard in effect as of the filing date of this application, or, if priority is claimed, the filing date of the earliest priority application in which the test standard appears.

What is claimed is:

1. A polishing pad for chemical mechanical polishing comprising:
a polishing layer having a polishing surface, a polishing layer interface surface opposite the polishing surface, a polishing layer thickness extending from the polishing surface to the polishing layer interface surface, and recesses extending from the polishing layer surface toward the polishing layer interface surface, wherein a depth of the recesses is at least 80% the polishing layer thickness,
a subpad layer having a subpad interface surface adjacent to the polishing layer interface surface and a bottom surface opposite the subpad interface surface, the subpad layer comprising a subpad material,
wherein the subpad layer has a thermal conductivity of 1 to 35 Watts/m-K.

2. The polishing pad of claim 1 wherein the recesses extend to the polishing layer interface surface.

3. The polishing pad of claim 1 wherein the recesses expose the subpad interface surface.

4. The polishing pad of claim 1 wherein the subpad layer has a consistent thermal conductivity throughout the subpad material.

5. The polishing pad of claim 1 wherein the subpad material comprises boron nitride particles in a polymeric matrix material.

6. The polishing pad of claim 5 wherein the boron nitride particles are present in an amount of 40 to 90 weight percent based on total weight of the boron nitride and the polymeric matrix material.

7. The polishing pad of claim 5 wherein the polymeric matrix material comprises a silicone composition.

8. The polishing pad of claim 7 wherein the silicone composition comprises 2 to 80 weight percent silicone adhesive and 20 to 98 weight percent silicone rubber based on total weight of the silicone composition.

9. The polishing pad of claim 4 wherein the subpad material is provided on a woven or non-woven material scaffold.

10. A method of polishing comprising
providing a substrate to be polished
providing the polishing pad as in claim 1 on a platen
providing a slurry on the polishing pad,
polishing by moving the substrate relative to the polishing pad, wherein the platen includes thermal control features.
